(19) United States
(12) Patent Application Publication
(10) Pub. No.: US 2004/0060812 A1
(43) Pub. Date: Apr. 1, 2004

(54) Method for modulating stress in films deposited using a physical vapor deposition (PVD) process

(75) Inventors: Jr-Jyan Chen, Santa Clara, CA (US); Harald Herchen, Los Altos, CA (US); Kenny King-Tai Ngan, Fremont, CA (US)

Correspondence Address: Patent Counsel, Applied Materials, Inc., P.O. Box 450A, Santa Clara, CA, 95052, US

(73) Assignee: Applied Materials, Inc.

(21) Appl. No.: 10/256,660

(22) Filed: Sep. 27, 2002

(51) Int. Cl. C23C 14/32

(52) U.S. Cl. 204/192.3; 204/192.12; 204/192.17; 204/192.22

(57) ABSTRACT

A method of controlling intrinsic stress in metal films deposited on a substrate using physical vapor deposition (PVD) techniques is disclosed. The film stress is controlled, by applying a bias power to the substrate during the deposition process. The magnitude of the bias power applied to the substrate modulates the film stress such that as-deposited material layers have an intrinsic stress that may be either tensile or compressive. Also, a reflected bias power may be applied to the substrate during the deposition process, in addition to the bias power. The magnitude of the reflected bias power in combination with the bias power also modulates the film stress such that as-deposited material layers have an intrinsic stress that may be either tensile or compressive.

### BACKGROUND OF THE INVENTION

1. Field of the Invention

The present invention relates to methods of depositing films using physical vapor deposition (PVD) techniques and, more particularly to a method of modulating intrinsic stress in films deposited using physical vapor deposition (PVD) techniques.

2. Description of the Related Art

Driven by market demands for high performance and small device dimensions, wafer-level packaging is being investigated as an interconnect structure of choice of for next generation integrated circuit (IC) manufacturing. In particular, as semiconductor manufacturing technologies move from 200 mm (millimeter) to 300 mm, the large wafer size and high input/output (I/O) density on IC's makes wafer-level packaging (e.g., flip chip structures) a cost effective alternative when compared with wire-bonding structures.

In flip-chip structures, solder bumps formed on the surface of the semiconductor wafer are used for interconnecting bonding pads. Typically, an under bond metal (UBM) stack is formed between the semiconductor wafer surface and the solder bumps. The UBM stack may comprise one or more metal layers that serve as adhesion layers, barrier layers, and/or wetting layers for the solder bumps. The UMB stacks may typically include for example, Ti/NiV, Ti/Cu, Al/NiV/Cu and TiW/CuCr/Cu, among others.

The UMB metal layers may be formed on a semiconductor wafer using, for example, a physical vapor deposition (PVD) process. In PVD processes, a target comprising a desired coating material is bombarded by ions accelerated thereto to dislodge and eject target material from the target, which is then deposited on a substrate.

Such PVD deposited material layers typically have an intrinsic stress whose magnitude is dependent on the temperature used during the deposition process. The intrinsic stress may be either tensile (e.g., positive in value) or compressive (e.g., negative in value).

Film stress is an important factor to ensure the integrity and/or reliability of semiconductor devices. For example, high tensile stresses may form cracks in the as-deposited material layer, while high compressive stresses may cause material layers to peel away from the substrate surface.

Thus, a need exists in the art for a method of controlling intrinsic stress in films deposited using physical vapor deposition (PVD) techniques.

### SUMMARY OF THE INVENTION

A method of controlling intrinsic stress in metal films deposited on a substrate using physical vapor deposition (PVD) techniques is described. The film stress is controlled, by applying a bias power to the substrate during the deposition process. The magnitude of the bias power applied to the substrate modulates the film stress such that as-deposited material layers have an intrinsic stress that may be either tensile or compressive. Also, a reflected bias power may be applied to the substrate during the deposition process, in addition to the bias power. The magnitude of the reflected bias power in combination with the bias power also modulates the film stress such that as-deposited material layers have an intrinsic stress that may be either tensile or compressive.

Metal layers formed having controlled intrinsic stress may be used in under bond metal (UMB) stacks for solder bump technology. For a solder bump fabrication processes, a preferred process sequence includes providing a substrate having an interconnect pattern defined in a dielectric material layer. A under bond metal (UMB) stack is deposited on the interconnect pattern defined in the dielectric material by applying a bias power to the substrate during the physical vapor deposition (PVD) process. Thereafter, the solder bump is completed by filling the interconnect pattern defined in the dielectric material with solder.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a cross-sectional schematic view of a physical vapor deposition (PVD) chamber that can be used to practice embodiments described herein;

FIG. 2 depicts a cross-sectional view of electrical circuitry attached to the pedestal assembly of FIG. 1;

FIG. 3 is a graph of the stress of a nickel-vanadium film plotted as a function of the pedestal temperature;

FIG. 4 is a graph of the stress of a nickel-vanadium film plotted as a function of the bias power applied to the substrate support;

FIG. 5 is a graph of the stress of a nickel-vanadium film plotted as a function of the reflected bias power applied to the substrate support;

FIG. 6 is a graph of the stress of a copper film plotted as a function of bias power applied to the substrate support; and

FIGS. 7A-7C illustrate schematic cross-sectional views of a substrate at different stages of a solder bump fabrication sequence.

### DETAILED DESCRIPTION OF THE PREFERRED EMBODIMENT

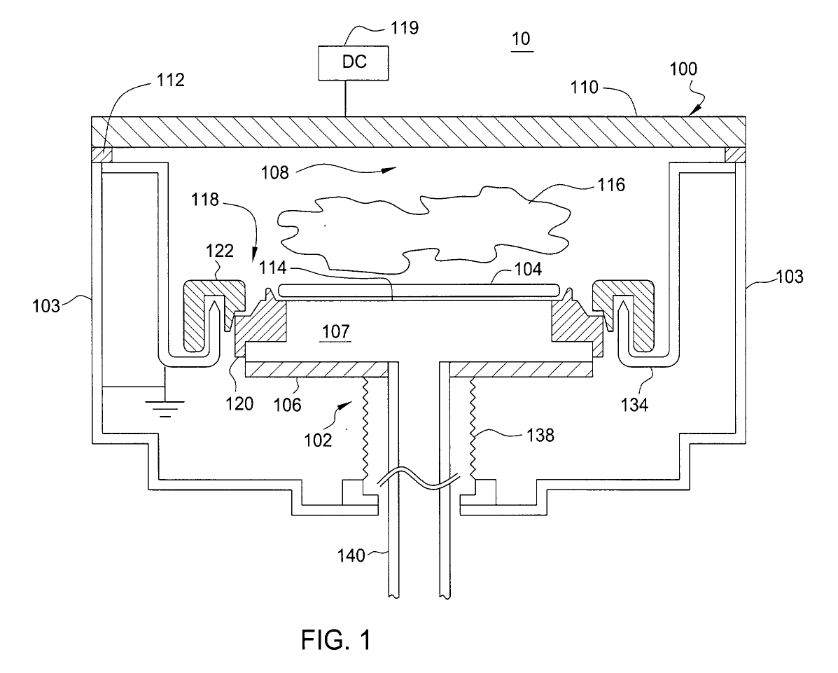

FIG. 1 depicts a schematic cross-sectional view of a physical vapor deposition (PVD) process chamber 10 that can be used to practice embodiments described herein. Details of the physical vapor deposition (PVD) process chamber are described in commonly assigned U.S. Pat. No. 6,215,640 entitled “Apparatus and Method for Actively Controlling Surface Potential of an Electrostatic Chuck” issued Apr. 10, 2001; U.S. Pat. No. 5,737,177 entitled “Apparatus and Method for Actively Controlling the DC Potential of a Cathode Pedestal” issued Apr. 7, 1998, and which are herein incorporated by reference. The salient features of PVD process chamber 10 are briefly described below.

The PVD process chamber 10 generally includes a vacuum chamber 100. The vacuum chamber 100 comprises a set of walls 103 that define a volume. A pedestal assembly 102 is positioned within the volume defined by walls 103. The PVD process chamber is typically maintained at a pressure within a range of about 1 mtorr to about 20 torr.

The pedestal assembly 102 comprises a pedestal 106 and a susceptor 107. The susceptor 107 has a surface 114 that supports a wafer 104. The pedestal 106 is connected to a lift mechanism 138 or other actuator disposed through the bottom portion of the chamber 100. The pedestal assembly may be maintained at a temperature less than about 200° C.

A chamber lid 110 at the top of the chamber 100 contains deposition target material. The target material may comprise metals including for example, titanium, tungsten, copper, aluminum and tantalum, among others, as well as alloys such as, for example nickel-vanadium, among others. Alternatively, a separate target (not shown) may be suspended from the chamber lid 110. The target provides a sputtering surface positioned to deposit sputtered material onto a top surface of the wafer 104. The chamber lid 110 is negatively biased by a sputter power source 119 to form a cathode.

The chamber lid 110 is electrically insulated from the remainder of the chamber 100. Specifically, an insulator ring 112, electrically isolates the chamber lid 110 from a grounded annular shield member 134, so that a negative voltage may be maintained on the target.

Sputter deposition processes are typically performed using a process gas such as an inert gas (e.g., argon (Ar), helium (He), xenon (Xe) and neon (Ne)) that is provided to the chamber 100 at a selected flow rate regulated by a mass flow controller. For nitride formation (e.g., titanium nitride (TiN), nickel vanadium nitride (NiVN)) a nitrogen-containing gas (e.g., nitrogen (N₂)) is provided to the chamber 100 to react with the sputtered target material.

The sputter power source 119 applies a negative voltage to the target in the chamber lid 110 with respect to the grounded annular shield member 134 so as to excite the inert gas provided to the chamber into a plasma state. Ions from the plasma bombard the target surface and sputter target material from the target. The sputter power source 119 used for target biasing purposes may be any type of power supply including DC, pulsed DC, AC, RF and combinations thereof. Sputter powers of up to about 50 kwatts may be used.

The vacuum chamber 100 includes a ring assembly 118 that prevents deposition from occurring in unwanted locations such as, upon the sides of the susceptor 107, beneath the pedestal. Specifically, a waste ring 120 and cover ring 122 prevent sputtered material from being deposited on surfaces other than the substrate.

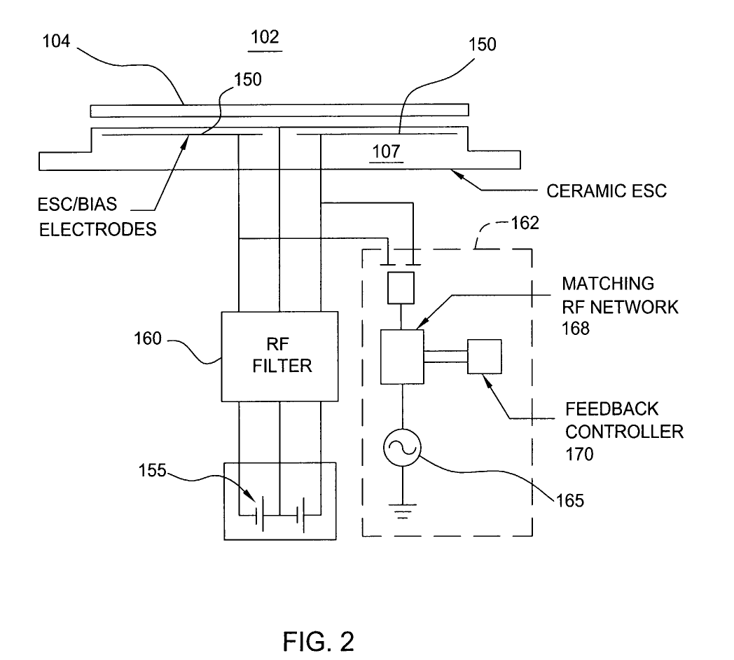

Referring to FIG. 2, the susceptor 107 may include an electrostatic chuck (ESC). The electrostatic chuck may comprise a dielectric material such as for example, ceramic. Embedded within the electrostatic chuck may be one or more electrodes 150. The one or more electrodes 150 in the electrostatic chuck are coupled to an ESC electrode power supply 155 through an RF filter 160. The ESC electrode power supply 155 may be for example, a DC power supply.

In use, once a plasma 116 is formed in a reaction zone 108 above the wafer 104 (FIG. 1), the plasma self-biases the wafer disposed on the ESC to a nominal DC value. Thereafter, the ESC electrode power supply 155 applies a voltage through RF filter 160 to the one or more electrodes 150. A difference in potential between the electrode voltage and the self-bias voltage on the wafer causes oppositely charged particles to accumulate on the underside of the wafer and on the surface of the electrostatic chuck (ESC), such that these accumulating charges form an attractive force between the wafer and the electrostatic chuck. As a result, the wafer is electrostatically retained on the chuck surface.

Additionally, substrate bias circuitry 162 provides a bias to the wafer 104 to direct the ionized metal particles toward the wafer 104. The substrate bias circuitry 162 includes a bias RF power supply 165 that is coupled to the susceptor 107 through a matching network 168. Additionally, a feedback controller 170 controls the bias power along with a reflected bias power that is applied to the wafer 104.

Preferably, the controller 170 is a programmable microprocessor, but other switching controls can be utilized. Typically, the wafer bias power ranges from about 3.2×10⁻³ watts/mm² to about 1.6×10⁻² watts/mm². A reflected bias power up to about 9.6×10⁻³ watts/mm² may be used.

It is believed that the magnitude of the bias power controls the intrinsic stress of as-deposited films by changing the force with which the ionized metal particles bombard the surface of the wafer. In particular, as the magnitude of the power is increased the force with which the ionized metal particles bombard the surface of the wafer is reduced. Alternatively, the magnitude of the bias power in combination with the reflected bias power may be used to control the intrinsic stress of the as-deposited films by changing the force with which ionized metal particles bombard the surface of the wafer.

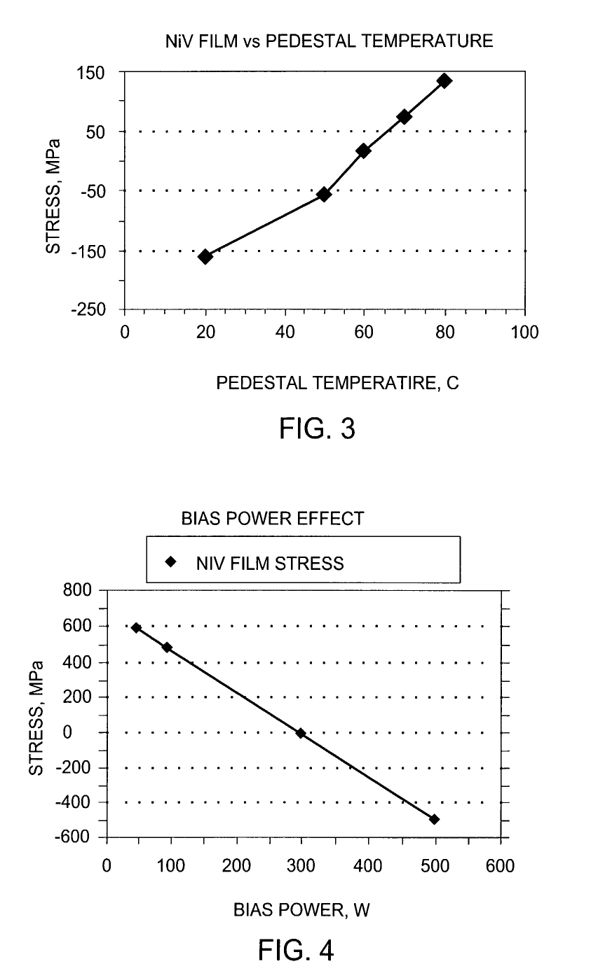

FIG. 3 is a graph of the stress of a nickel-vanadium film plotted as a function of the temperature of the substrate support during deposition. A nickel-vanadium target comprising 7% vanadium and 93% nickel was used. Nickel-vanadium films were sputter deposited using a target power of about 11 kilowatts, argon flow of about 25 sccm (standard cubic centimeters/minute), a chamber pressure of about 1.5 mtorr and a wafer bias power of about 250 watts (7.8×10⁻³ watts/mm²). Nickel-vanadium films were deposited at temperatures ranging between about 20° C. to about 80° C. As indicated in FIG. 3, temperatures above about 60° C. provide nickel-vanadium films with tensile stress, while temperatures below about 60° C. provide nickel-vanadium films with compressive stress.

FIG. 4 is a graph of the stress of a nickel-vanadium film plotted as a function of a wafer bias power that was applied to the substrate support during deposition. A nickel-vanadium target comprising 7% vanadium and 93% nickel was used. Nickel-vanadium films were sputter deposited using a target power of about 11 kilowatts, argon flow of about 25 sccm (standard cubic centimeters/minute), a susceptor temperature of about 20° C. and a chamber pressure of about 1.5 mtorr. Nickel-vanadium films were deposited using wafer bias powers that ranged between 50 watts (1.7×10⁻³ watts/mm²) to about 500 watts (1.7×10⁻² watts/mm²). As indicated in FIG. 4, at a deposition temperature of 20° C., wafer bias powers below about 300 watts (1×10⁻² watts/mm²) provided nickel-vanadium films with tensile stress, while wafer bias powers above about 300 watts provided nickel-vanadium films with compressive stress. In contrast, as shown in FIG. 3, nickel-vanadium films deposited at a temperature of 20° C. without wafer bias powers had a compressive stress. Thus, by modulating the bias power, the intrinsic stress of films deposited using physical vapor deposition (PVD) techniques may be controlled.

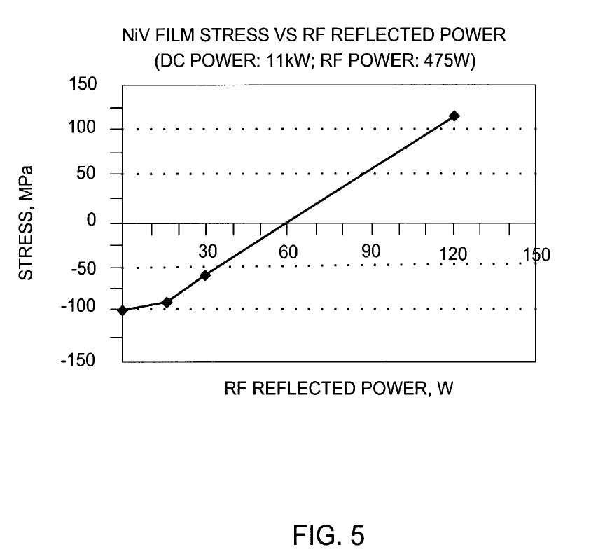

FIG. 5 is a graph of the stress of a nickel-vanadium film plotted as a function of the bias power in combination with a reflected bias power that was applied to the substrate support during deposition. A nickel-vanadium target comprising 7% vanadium and 93% nickel was used. Nickel-vanadium films were sputter deposited using a target power of about 11 kilowatts, an argon flow of about 25 sccm (standard cubic centimeters/minute), a susceptor temperature of about 20° C., a chamber pressure of about 1.5 mtorr and a wafer bias power of about 450 watts (1.4×10⁻² watts/mm²). Nickel-vanadium films were deposited using reflected wafer bias powers that ranged between 0 watts to about 120 watts (3.8×10⁻³ watts/mm²). As indicated in FIG. 5, at a wafer bias power of about 450 watts (1.4×10⁻² watts/mm²), reflected bias powers above about 60 watts (1.9×10⁻³ watts/mm²) provide nickel-vanadium films with tensile stress, while reflected bias powers below about 60 watts provide nickel-vanadium films with compressive stress. Thus, by modulating the bias power in combination with the reflected bias power, the intrinsic stress of films deposited using physical vapor deposition (PVD) techniques may also be controlled.

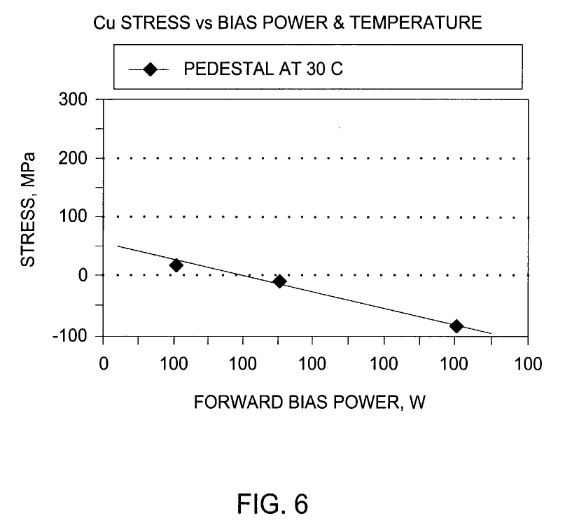

FIG. 6 is a graph of the stress of a copper film plotted as a function of the wafer bias power that was applied to the substrate support during deposition. Copper films were sputter deposited using a target power of about 8 kilowatts, argon flow of about 80 sccm (standard cubic centimeters/minute), a chamber pressure of about 4.5 mtorr and a wafer bias power of about 50 watts (1.7×10⁻³ watts/mm²) to about 500 watts (1.7×10⁻² watts/mm²). Copper films were deposited at a temperature of about 30° C. As indicated in FIG. 6, at 30° C., the stress in the deposited copper film is tensile at wafer bias powers below about 200 watts (6.9×10⁻³ watts/mm²), while wafer bias powers above about 200 watts provide copper films with compressive stress.

### Integrated Circuit Fabrication Process

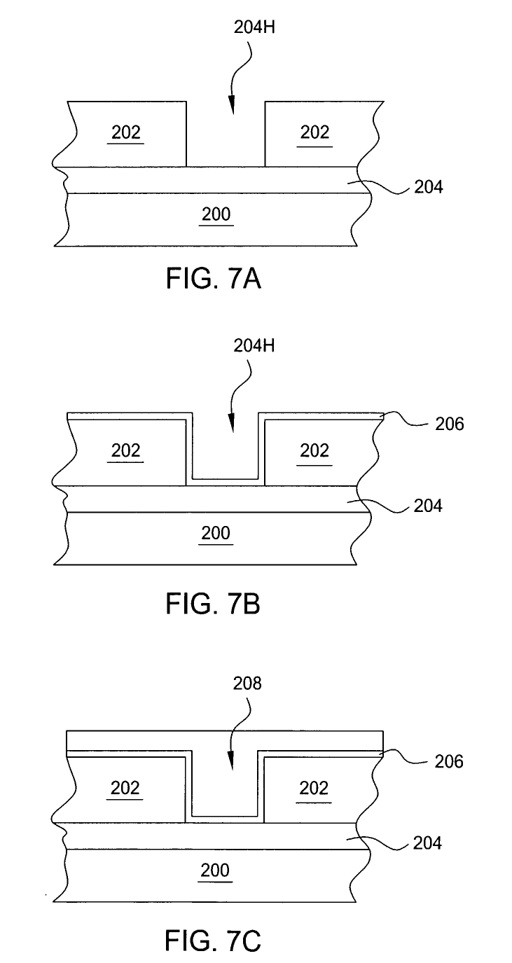

FIGS. 7A-7C illustrate cross-sectional views of a substrate at different stages of a solder bump fabrication sequence incorporating an under bond metal (UBM) stack of the present invention. FIG. 7A, for example, illustrates a cross-sectional view of a substrate 200 having metal contacts 204 and a dielectric layer 202 formed thereon. The substrate may comprise a semiconductor material such as, for example, silicon (Si), germanium (Ge), or gallium arsenide (GaAs). The dielectric layer 202 may comprise an insulating material such as, for example, silicon oxide or silicon nitride. The metal contacts 204 may comprise for example, copper (Cu). Apertures 204H may be defined in the dielectric layer 202 to provide openings over the metal contacts 204. The apertures 204H may be defined in the dielectric layer 202 using conventional lithography and etching techniques.

Referring to FIG. 7B, an under bond metal (UMB) stack 206 is formed in the apertures 204H defined in the dielectric layer 202. The under bond metal (UMB) stack 206 comprises a NiV/Cu stack. The under bond metal (UMB) stack 206 is formed using the physical vapor deposition techniques described above with respect to FIGS. 4-6. The thickness of the under bond metal (UMB) stack 206 is typically about 100 Å to about 10,000 Å. Thereafter, the apertures 204H are filled with solder 208 using a suitable deposition process as shown in FIG. 7C.

While foregoing is directed to the preferred embodiment of the present invention, other and further embodiments of the invention may be devised without departing from the basic scope thereof, and the scope thereof is determined by the claims that follow.

1. A method of depositing metal films on a substrate, comprising:
generating a plasma; and
depositing at least one metal film on a substrate from a target with the plasma, wherein the stress in the deposited at least one metal film is determined by applying a bias power to the substrate as the at least one metal film is deposited.

2. The method of claim 1 further comprising applying a reflected bias power to the substrate as the at least one metal film is deposited.

3. The method of claim 1 wherein the plasma comprises a nitrogen-containing gas to form a metal nitride film on the substrate.

4. The method of claim 1 wherein the target comprises one or more materials selected from the group consisting of nickel-vanadium (NiV), titanium (Ti), tungsten (W), aluminum (Al), copper (Cu), tantalum (Ta) and combinations thereof.

5. The method of claim 1 wherein the plasma comprises an inert gas selected from the group consisting of argon (Ar), helium (He), xenon (Xe) neon (Ne) and combinations thereof.

6. The method of claim 1 wherein the bias power applied to the substrate is within a range of about 3.2×10⁻³ watts/mm² to about 1.6×10⁻² watts/mm².

7. The method of claim 2 wherein the reflected bias power is less than about 9.6×10⁻³ watts/mm².

8. The method of claim 1 wherein the substrate is maintained at a temperature less than about 200° C.

9. The method of claim 1 wherein the at least one metal film is deposited at a pressure within a range of about 1 mtorr to about 10 torr.

10. A method of depositing metal films on a substrate, comprising:
generating a plasma; and
depositing at least one metal film on a substrate from a target with the plasma, wherein the stress in the deposited at least one metal film is determined by applying a bias power to the substrate and tuning a reflected bias power as the at least one metal film is deposited.

11. The method of claim 10 wherein the plasma comprises a nitrogen-containing gas to form a metal nitride film on the substrate.

12. The method of claim 10 wherein the target comprises one or more materials selected from the group consisting of nickel-vanadium (NiV), titanium (Ti), tungsten (W), aluminum (Al), copper (Cu), tantalum (Ta) and combinations thereof.

13. The method of claim 10 wherein the plasma comprises an inert gas selected from the group consisting of argon (Ar), helium (He), xenon (Xe) neon (Ne) and combinations thereof.

14. The method of claim 10 wherein the bias power applied to the substrate is within a range of about 3.2×10⁻³ watts/mm² to about 1.6×10⁻² watts/mm².

15. The method of claim 10 wherein the reflected bias power is less than about 9.6×10⁻³ watts/mm².

16. The method of claim 10 wherein the substrate is maintained at a temperature less than about 200° C.

17. The method of claim 10 wherein the at least one metal film is deposited at a pressure within a range of about 1 mtorr to about 10 torr.

18. A method of depositing metal films on a substrate, comprising:
generating a plasma; and
depositing at least one metal film on a substrate from a target with the plasma, wherein the stress in the at least one metal film is determined by applying a bias power within a range of about 3.2×10⁻³ watts/mm² to about 1.6×10⁻² watts/mm² to the substrate and tuning a reflected bias power less of than about 9.6×10⁻³ watts/mm² as the at least one metal film is deposited.

19. The method of claim 18 wherein the plasma comprises a nitrogen-containing gas to form a metal nitride film on the substrate.

20. The method of claim 18 wherein the target comprises one or more materials selected from the group consisting of nickel-vanadium (NiV), titanium (Ti), tungsten (W), aluminum (Al), copper (Cu), tantalum (Ta) and combinations thereof.

21. The method of claim 18 wherein the plasma comprises an inert gas selected from the group consisting of argon (Ar), helium (He), xenon (Xe) neon (Ne) and combinations thereof.

22. The method of claim 18 wherein the substrate is maintained at a temperature less than about 200° C.

23. The method of claim 15 wherein the at least one metal film is deposited at a pressure within a range of about 1 mtorr to about 10 torr.

24. A method of forming a solder bump on a substrate, comprising:
providing a substrate having thereon an interconnect pattern defined in a dielectric material layer;
generating a plasma; and
depositing at least one metal film on the interconnect pattern from a target with the plasma, wherein the stress in the deposited at least one metal film is determined by applying a bias power to the substrate as the at least one metal film is deposited.

25. The method of claim 24, further comprising filling the interconnect pattern with solder after the at least one metal film is deposited therein.

26. The method of claim 24 further comprising applying a reflected bias power to the substrate as the at least one metal film is deposited.

27. The method of claim 24 wherein the plasma comprises a nitrogen-containing gas to form a metal nitride film on the substrate.

28. The method of claim 24 wherein the target comprises one or more materials selected from the group consisting of nickel-vanadium (NiV), titanium (Ti), tungsten (W), aluminum (Al), copper (Cu), tantalum (Ta) and combinations thereof.

29. The method of claim 24 wherein the plasma comprises an inert gas selected from the group consisting of argon (Ar), helium (He), xenon (Xe) neon (Ne) and combinations thereof.

30. The method of claim 24 wherein the bias power applied to the substrate is within a range of about 3.2×10⁻³ watts/mm² to about 1.6×10⁻² watts/mm².

31. The method of claim 26 wherein the reflected bias power is less than about 9.6×10⁻³ watts/mm².

32. The method of claim 24 wherein the substrate is maintained at a temperature less than about 200° C.

33. The method of claim 24 wherein the at least one metal film is deposited at a pressure within a range of about 1 mtorr to about 10 torr.

34. A method of forming a solder bump on a substrate, comprising:
providing a substrate having thereon an interconnect pattern defined in a dielectric material layer;
generating a plasma; and
depositing at least one metal film on the interconnect pattern from a target with the plasma, wherein the stress in the deposited at least one metal film is determined by applying a bias power to the substrate and tuning a reflected bias power as the at least one metal film is deposited.

35. The method of claim 34, further comprising filling the interconnect pattern with solder after the at least one metal film is deposited therein.

36. The method of claim 34 wherein the plasma comprises a nitrogen-containing gas to form a metal nitride film on the substrate.

37. The method of claim 34 wherein the target comprises one or more materials selected from the group consisting of nickel-vanadium (NiV), titanium (Ti), tungsten (W), aluminum (Al), copper (Cu), tantalum (Ta) and combinations thereof.

38. The method of claim 34 wherein the plasma comprises an inert gas selected from the group consisting of argon (Ar), helium (He), xenon (Xe) neon (Ne) and combinations thereof.

39. The method of claim 34 wherein the bias power applied to the substrate is within a range of about 3.2×10⁻³ watts/mm² to about 1.6×10⁻² watts/mm².

40. The method of claim 34 wherein the reflected bias power is less than about 9.6×10⁻³ watts/mm².

41. The method of claim 34 wherein the substrate is maintained at a temperature less than about 200° C.

42. The method of claim 34 wherein the at least one metal film is deposited at a pressure within a range of about 1 mtorr to about 10 torr.

43. A method of forming a solder bump on a substrate, comprising:
providing a substrate having thereon an interconnect pattern defined in a dielectric material layer;
generating a plasma; and
depositing at least one metal film on the interconnect pattern from a target with the plasma, wherein the stress in the at least one metal film is determined by applying a bias power within a range of about 3.2×10⁻³ watts/mm² to about 1.6×10⁻² watts/mm² to the substrate and tuning a reflected bias power less of than about 9.6×10⁻³ watts/mm² as the at least one metal film is deposited.

44. The method of claim 43, further comprising filling the interconnect pattern with solder after the at least one metal film is deposited.

45. The method of claim 42 wherein the plasma comprises a nitrogen-containing gas to form a metal nitride film on the substrate.

46. The method of claim 42 wherein the target comprises one or more materials selected from the group consisting of nickel-vanadium (NiV), titanium (Ti), tungsten (W), aluminum (Al), copper (Cu), tantalum (Ta) and combinations thereof.

47. The method of claim 42 wherein the plasma comprises an inert gas selected from the group consisting of argon (Ar), helium (He), xenon (Xe) neon (Ne) and combinations thereof.

48. The method of claim 42 wherein the substrate is maintained at a temperature less than about 200° C.

49. The method of claim 42 wherein the at least one metal film is deposited at a pressure within a range of about 1 mtorr to about 10 torr.
